(19) United States
(12) Patent Application Publication
(10) Pub. No.: US 2011/0048927 A1
(43) Pub. Date: Mar. 3, 2011

(54) SPUTTERING APPARATUS AND SPUTTERING METHOD

(76) Inventors: Naoki Morimoto, Shizuoka (JP); Tomoyasu Kondo, Shizuoka (JP); Kokichi Kamada, Shizuoka (JP); Kyuzo Nakamura, Kanagawa (JP)

(21) Appl. No.: 12/991,800

(22) PCT Filed: Jun. 23, 2009
(86) PCT No.: PCT/JP2009/061398

§ 371 Date: Nov. 9, 2010

(30) Foreign Application Priority Data
Jun. 26, 2008 (JP) 2008-167174

(51) Int. Cl. C23C 14/35

(52) U.S. Cl. 204/192.12; 204/298.17

(57) ABSTRACT

An inexpensive sputtering apparatus of simple construction is provided in which a film can be formed with good coating characteristics relative to each of micropores of high aspect ratio. The sputtering apparatus has: a target lying opposite to a substrate W which is disposed inside a vacuum chamber; a magnet assembly which generates a tunnel-shaped magnetic field in front of a sputtering surface of the target; a gas introduction means which introduces a sputtering gas into the vacuum chamber; and a sputtering power supply which charges negative potential to the target. There are provided magnetic field generating means to generate a vertical magnetic field of such a nature that vertical lines of magnetic force M pass through a sputtering surface and through an entire surface of the substrate at a predetermined distance from one another.

### TECHNICAL FIELD

The present invention relates to a sputtering apparatus for, and a sputtering method for, forming a film on a surface of a substrate to be processed, the apparatus and the method being in particular of a DC magnetron system.

### BACKGROUND ART

The sputtering apparatus of this kind of DC magnetron system is used in a film forming step in, e.g., the manufacturing of semiconductor devices. Accompanied by the recent miniaturization of the wiring patterns, this kind of sputtering apparatus is strongly required to be able to form a film well with good coating characteristics throughout the entire surfaces of the substrate to be processed relative to micropores (via holes) of high aspect ratio, i.e., required to have an improvement in coverage.

Generally, in the above-mentioned sputtering apparatus, a magnet assembly in which a plurality of magnets are provided is disposed in the rear of the target (i.e., on the side lying opposite to the sputtering surface) by alternately changing the polarity. This magnet assembly is caused to generate a tunnel-like magnetic field in front of the target (on the side of the sputtering surface). By collecting the electrons that are ionized in front of the target and the secondary electrons that are generated by sputtering, the electron density in front of the target is enhanced to thereby enhance the plasma density.

In this kind of sputtering apparatus, the target will be preferentially sputtered in those regions, out of the target, which are under the influence of the above-mentioned magnetic field. As a result, in case the above-mentioned regions are present near the centre of the target from the viewpoint of stability of electric discharging, improvement in the efficiency of utilizing the target, and the like, the amount of erosion of the target at the time of sputtering becomes larger near the center of the target. In such a case, the particles of the target material as sputtered off from the target (e.g., the metallic particles; hereinafter referred to as “sputtered particles”) will be incident at an inclined angle into, and get adhered to, the peripheral portion of the substrate. As a result, when such a target is used in the film forming for the above-mentioned film formation for the above-mentioned purpose, it is conventionally known that asymmetry of the coverage at the outer peripheral portion of the substrate will become a problem.

In order to solve this kind of problem, there is known a sputtering apparatus in, e.g., Patent Document 1. In the sputtering apparatus, a first sputtering target is disposed above a stage on which is placed a substrate inside the vacuum chamber, the first sputtering target being disposed substantially in parallel with the surface of the stage. A second sputtering target is disposed in an inclined manner relative to the surface of the stage slantingly above the stage. In other words, a plurality of cathode units are disposed inside the vacuum chamber.

However, if a plurality of cathode units are disposed inside the vacuum chamber like in the example as described in the above-mentioned Patent Document 1, there is a disadvantage in that the apparatus becomes complicated in construction, and that a sputtering power supply and a magnet assembly will be needed depending on the number of the targets, resulting in an increase in the number of parts and a consequent increase in cost. Further, there is also a disadvantage in that the efficiency of utilizing the targets as a whole becomes poor, resulting in an increase in cost of manufacturing the products.

### Patent Document 1: JP-A-2008-47661

### DISCLOSURE OF THE INVENTION

### Problems to be Solved by the Invention

In view of the above-mentioned points, this invention has a problem of providing an inexpensive sputtering apparatus which is arranged to be capable of forming a film on each of micropores of high aspect ratio throughout the entire surface of the substrate, as well as of providing a sputtering method.

### Means for Solving the Problems

In order to solve the above-mentioned problems, this invention is a sputtering apparatus for forming a film on a surface of a substrate disposed in a vacuum chamber. The sputtering apparatus comprises: a target disposed so as to lie opposite to the substrate; a magnet assembly for generating a magnetic field in front of a sputtering surface of the target; a gas introduction means for introducing a sputtering gas into the vacuum chamber, and a sputtering power supply for charging the target with a negative potential. The sputtering apparatus further comprises a vertical magnetic field generating means for generating a vertical magnetic field of such a nature that vertical lines of magnetic force pass through a sputtering surface of the target and through an entire surface of the substrate, the vertical lines of magnetic force being at a predetermined distance from one another.

According to this invention, there is generated the vertical magnetic field of such a nature that vertical lines of magnetic force pass through the sputtering surface of the target and the entire surface of the substrate, the vertical lines of magnetic force being at a predetermined distance from one another. Since the sputtered particles scattered by sputtering out of the sputtering surface of the target have positive electric charges, the direction thereof is changed by the above-mentioned vertical magnetic field, and the sputtered particles tend to be incident into, and deposited on, the substrate substantially vertically relative to the substrate. As a result, if the sputtering apparatus of this invention is used in the film-forming step of manufacturing the semi-conductor devices, a film can be formed at good coating characteristics even relative to the micropores (via holes) of high aspect ratio throughout the entire surface of the substrate. In other words, the problem of asymmetry of coverage is resolved and the in⁻plane uniformity improves.

As described above, according to this invention, since the magnet assembly which determines the region for preferential sputtering of the target remains as it is, the efficiency of utilizing the target will not be lowered. In addition, unlike in the above-mentioned conventional art, since a plurality of cathode units are not disposed in the sputtering apparatus itself, the manufacturing cost and the running cost of the apparatus can be kept low.

In this invention, preferably, the magnetic field generating means comprises: at least two coils disposed about a reference axis which connects the target and the substrate, and also at a predetermined distance from each other as seen in a longitudinal direction of the reference axis; and a power supply apparatus which enables to supply electricity to each of the coils. In this arrangement, as compared with a case in which the apparatus construction is modified in order to mount a plurality of cathode units, the construction of this invention is extremely simple. And by appropriately changing the distance between the coils, the number of winding of each of the coils, the direction of current and the current value to the coils, and the like, it can be materialized to generate the vertical magnetic field at a predetermined magnetic field strength of such a nature that vertical lines of magnetic force pass through the sputtering surface of the target and through the entire surface of the substrate.

Further, in order to solve the above-mentioned problems, this invention is a sputtering method comprising: generating a vertical magnetic field of such a nature that vertical lines of magnetic force pass through a sputtering surface of the target and through an entire surface of the substrate, the vertical lines of magnetic force being at a predetermined distance from one another; introducing a sputtering gas into the vacuum chamber and charging the target with a negative DC potential in a state in which the magnetic field is kept generated in front of the sputtering surface of the target, thereby forming a plasma atmosphere; and sputtering the target to cause the sputtered particles to get adhered to, and deposited on, the surface of the substrate, thereby forming a film.

In this invention, in order to form a film at a uniform thickness throughout the entire surface of the substrate at a good efficiency without the particles of the target material being deactivated under the influence of the vertical magnetic field, preferably, the vertical magnetic field is generated in a direction from the sputtering surface toward the substrate.

### BEST MODE FOR CARRYING OUT THE INVENTION

With reference to the accompanying drawings, a description will now be made of a sputtering apparatus according to one embodiment of this invention. As shown in FIG. 1, the sputtering apparatus 1 is of a DC magnetron sputtering system and is provided with a vacuum chamber 2 in which vacuum atmosphere can be formed. On a ceiling portion of the vacuum chamber 2 there is mounted a cathode unit C. In the following description, the ceiling side of the vacuum chamber 2 is defined as “upper” side and the bottom side thereof is defined as “lower” side.

The cathode unit C is provided with a target 3, and a magnet assembly 4 which generates a tunnel-shaped magnetic field in front of the sputtering surface (lower surface) 3a of the target 3. The target 3 is made of a material appropriately selected depending on the composition of the thin film to be formed on the substrate W to be processed, e.g., is made of Cu, Ti and Ta. The target 3 is manufactured into a predetermined shape (e.g., into a circle as seen in plan view) in a known method corresponding to the shape of the substrate W to be processed such that the area of the sputtering surface 3a becomes larger than the surface area of the substrate W. Further, the target 3 is electrically connected to a DC power supply 5 (sputtering power supply) of a known construction so that a predetermined negative potential is charged thereto.

The magnet assembly 4 is disposed on a side which opposes the sputtering surface 3a (i.e., on the upper side), and is made up of a disk-shaped yoke 4a which is disposed in parallel with the target 3, and a ring-shaped magnets 4b, 4c which are concentrically disposed on the lower surface of the yoke 4a by alternatively changing the polarity on the side of the target 3. The shape and number of the magnets 4b, 4c are appropriately selected depending on the magnetic field to be formed in front of the target 3 from the viewpoint of the stability in electric discharging, the improvement in the use efficiency of the target, and the like. For example, they may be made of a thin-piece shape or a bar shape or of a combination thereof. Further, an arrangement may also be made that the magnet assembly 4 is movable back and forth or rotatable on the rear surface side of the target 3.

At the bottom of the vacuum chamber 2 there is disposed a stage 6 in a manner to lie opposite to the target 3 and is so arranged that the substrate W can be held in alignment. Further, to the side wall of the vacuum chamber 2 there is connected a gas pipe 7 which introduces a sputtering gas such as argon gas. The other end of the gas pipe 7 is communicated with a gas source through a mass flow controller (not illustrated). Still furthermore, the vacuum chamber 2 has connected thereto an exhaust pipe 8a which is in communication with an evacuation means 8 made up of a turbo molecular pump, rotary pump, and the like.

In the sputtering apparatus in a state of the above-mentioned embodiment (corresponding to the conventional example), if the target 3 is sputtered, sputtering of the target 3 takes place preferentially in a region which is under the influence of the magnetic field to be generated by the magnet assembly 4. As a result, sputtered particles which are the particles of the target material tend to get scattered. Therefore, if the above-mentioned region lies near an intermediate position between, e.g., the center and the outermost periphery of the target, the amount of erosion Te of the target 3 during sputtering increases near the above-mentioned intermediate portion (see FIG. 2). In such a case, in the peripheral portion of the substrate W, the sputtered particles tend to be incident at an inclined angle into, and get deposited on, the substrate.

Now, the substrate W to be processed is obtained by forming a silicon oxide film (insulating film) I on the surface of a Si wafer and, thereafter, forming micropores H of high aspect ratio by patterning in the silicon oxide film. Therefore, when a thin film L such as a seed layer made of Cu or a barrier metal layer made of Ti or Ta, and the like is formed on this substrate W, there will occur a problem of non-asymmetry of coverage in the peripheral portion of the substrate W (see FIG. 2).

As a solution, in an embodiment of this invention, there was disposed a vertical magnetic field generating means which generates a vertical magnetic field such that vertical lines of magnetic force M pass, at an equal distance from each other, through the sputtering surface 3a of the target 3 and through the entire surface of the substrate W. The magnetic field generating means is made up of: an upper coil 11u and a lower coil 11d in which a wire 10 is respectively wound around two ring-shaped yokes 9 which are disposed on an outer wall of the vacuum chamber 2 at a predetermined distance from each other in the vertical direction about a reference axis CL which connects the center of the target 3 and the center of the substrate W; and a power supply apparatus 12 which enables to supply electric power to each of the coils 11u, 11d (see FIGS. 1 and 3a).

Here, the number of the coil and the number of winding of the wire 10 are appropriately set (e.g., 14 mm in diameter and 10 in number of winding) depending, e.g., on the dimension of the target 3, the distance between the target 3 and the substrate W, the rated current value of the power supply apparatus 12 and the strength (Gauss) of the magnetic field to be generated. In addition, in order to make the in-plane film thickness distribution substantially uniform throughout the surface of the substrate W at the time of film forming (i.e., to make the sputtering rate substantially uniform in the diametrical direction of the substrate W) when the vertical magnetic field is generated by the two upper and lower coils 11u, 11d as in the embodiment of this invention, it is preferable to set the vertical position of each of the coils 11u, 11d such that the distance (D1) between the lower end of the upper coil 11u and the target 3 and the distance (D2) between the upper end of the lower coil 11d and the substrate W become shorter than the distance D3 to the middle point Cp of the reference axis. In this case, the distance between the lower end of the upper coil 10u and the target 3, and the distance between the upper end of the lower coil 11d and the substrate W need not always coincide with each other. Depending on the arrangement of the apparatus, the upper and the lower coils 11u, 11d may be arranged to be disposed on the rear surface side of the target 3 and the substrate W, respectively.

The power supply apparatus 12 has a known construction which is provided with a control circuit (not illustrated) which is capable of freely changing the current value and current direction to each of the upper and the lower coils 11u, 11d. In this case, the energized current is set (e.g., below 15 A) such that the magnetic intensity becomes smaller than 100 Gauss when a vertical magnetic field is generated by charging power to the coils 11u, 11d. If the magnetic intensity exceeds 100 Gauss, the sputtered particles will be deactivated and, as a result, satisfactory film formation cannot be made. Further, in order for the sputtered particles not to be deactivated under the influence of the vertical magnetic field, the direction of the current to flow through each of the coils 11u, 11d will be controlled so that the downward vertical magnetic field is generated. A description has so far been made of an example in which a separate power supply apparatus 12 is provided in order to arbitrarily change the current value and the direction of current to each of the upper and lower coils 11u, 11d. However, in case each of the coils 11u, 11d is charged with electricity in the same current value and in the same direction of current, it may be so arranged that electricity is charged with a single power supply apparatus.

By arranging the sputtering apparatus 1 as described hereinabove, if the sputtered particles have positive electric charge when the target 3 is sputtered, the direction of the sputtered particles will be changed by the vertical magnetic field from the target 3 to the substrate W. The sputtered particles will thus be incident into, and get deposited on, the substrate W substantially vertically throughout the entire surface of the substrate W. As a result, by using the sputtering apparatus 1 according to the embodiment of this invention in the film forming step of manufacturing semiconductor devices, a predetermined thin film L can be formed with good coating characteristics even with respect to micropores H of high aspect ratio throughout the entire surface of the substrate W (i.e., the problem of asymmetry of coverage is resolved and the in-plane uniformity is improved (see FIG. 3).

As described above, according to the sputtering apparatus 1 of an embodiment of this invention, while leaving as it is the magnet assembly 4 to decide that region of the target 3 which is preferentially sputtered, the direction of the sputtered particles is arranged to be changed by each of the coils 11u, 11d of the vertical magnetic field generating means. As a result, since the efficiency of utilizing the target 3 is not lowered and, unlike the conventional art, since a plurality of cathode units are not used, the manufacturing cost and the running cost of the apparatus can be reduced. In addition, since only the upper and the lower coils 11u, 11d are disposed, the construction is extremely simpler than the one in which the arrangement of the apparatus is changed. The sputtering apparatus of this invention can therefore be manufactured by modifying the existing apparatus.

In the sputtering apparatus 1 according to this embodiment, the following arrangement may be employed in order to further improve the in-plane uniformity of coverage. That is, there may be disposed an anode electrode 21 and ground electrodes 22, 23 in a manner to enclose the space between the target 3 and the stage 6 within the vacuum chamber 2. Then, at the time of film forming, positive voltage is charged to the anode electrode 21 that is positioned on the side of the target 3. The ground electrodes 22, 23 that are positioned on the side of the stage 6 and that are divided from each other are connected to the ground potential. According to this arrangement, that orbit of the sputtered particles which is bent by the anode electrode 21 in the flight direction is corrected so as to be incident into the surface of the substrate W in a more vertical manner. In this case, the bias power supply 24 may be connected to the stage 6.

A description will now be made of an example of film forming by using the above-mentioned sputtering apparatus 1. In the example, as the substrate W on which a film is formed, there was used one which has formed a silicon oxide film I on the surface of a Si wafer and, thereafter, micropores H for wiring were formed in a known method by pattering in the silicon oxide film, and a Cu film L as a seed layer is formed by sputtering.

First, after having set in position the substrate W on the stage 6, the evacuation means 8 is operated to thereby evacuate the vacuum chamber 2 to a predetermined degree of vacuum (e.g., 10⁻⁵ Pa). At the same time, by operating the power supply apparatus 12 to apply power to the upper coil 11u and the lower coil 11d, a magnetic field is caused to be generated at a predetermined magnetic field strength such that the vertical lines of magnetic force M pass through the target 3 and through the entire surface of the substrate W at an equal distance from one another. Once the pressure in the vacuum chamber 2 has reached a predetermined value, predetermined negative potential is charged (power supply) from the DC power supply 5 to the target 3 while introducing argon gas of a predetermined flow amount into the vacuum chamber 2, whereby a plasma atmosphere is formed inside the vacuum chamber 2. In this case, electrons ionized in front of the sputtering surface 3a by the magnetic field from the magnet assembly 4 and the secondary electrons generated by the sputtering are captured, so that the plasma in front of the sputtering surface 3a becomes higher in density.

Argon ions in the plasma collide with the sputtering surface 3a so that the sputtering surface 3a gets sputtered and, as a result, Cu atoms and Cu ions get scattered off from the sputtering surface 3a toward the substrate W. At this time, Cu having a positive electric charge is caused to change the direction by the vertical magnetic field so that the sputtered particles tend to be incident substantially vertically into the entire surface of the substrate W and get deposited on the substrate W. As a result, a film is formed at good coating characteristics on the micropores H throughout the entire surface of the substrate W.

With reference to this embodiment, a description has been made of a case in which the upper coil 11u and the lower coil 11d are electrically charged to thereby generate a vertical magnetic field. However, the configuration is free as long as the vertical magnetic field can be generated so that the vertical lines of magnetic force M pass through the target 3 and through the entire surface of the substrate W at an equal distance to one another. It may therefore be so arranged that known sintered magnets are appropriately disposed inside and outside the vacuum chamber so as to form a vertical magnetic field.

### Example 1

In Example 1, Cu film was formed by using the sputtering apparatus as shown in FIG. 1 (without using an anode electrode 21 and ground electrodes 22, 23). As the substrate W there was used one which has formed a silicon oxide film throughout the entire surface of the Si wafer of 300 mm in diameter and which has subsequently formed micropores (40 nm in width and 140 nm in depth) in the silicon oxide film by patterning in a known method. As the target, there was used one whose composition ratio of Cu was 99% and which was manufactured into a sputtering surface of 400 mm in diameter. The distance between the target and the substrate was set to 400 mm and the distance between the lower end of the upper coil 10u and the target 3, and the distance between the upper end of the lower coil 11d and the substrate W were respectively set to 50 mm.

Further, as the film-forming conditions, Ar gas was used as the sputtering gas by introducing it at a flow rate of 15 sccm. In addition, the electric power to be charged to the target was set to 18 kW (electric current 30 A), and the electric current value to each of the coils was set to—15 A (a downward vertical magnetic field is generated). The sputtering time was set to 10 seconds, and the film forming of Cu film was performed.

After having formed a Cu film according to Example 1 as described above, the sputtering rate was measured out of the film thicknesses at the central portion and the peripheral portion of the substrate. It has been confirmed that the difference between the two was about 1 nm/S and that the uniformity in the film thickness distribution was high within the substrate plane. In addition, when the coverage of the micropores was confirmed respectively at the central portion and the peripheral portion by SEM pictures, it has been confirmed that a highly compact Cu film has been formed to cover the entire inner surfaces of the micropores.

### BRIEF DESCRIPTION OF THE DRAWINGS

FIG. 1 is a schematic sectional view of a sputtering apparatus according to one embodiment of this invention.

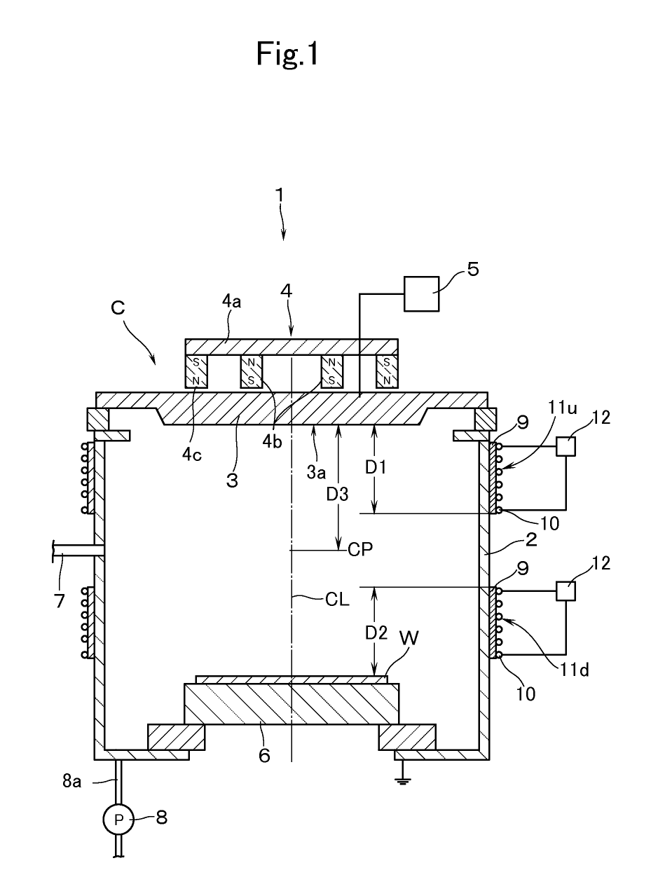

FIG. 2 is a schematic explanation of a state in which a film was formed by using the sputtering apparatus relating to the conventional art.

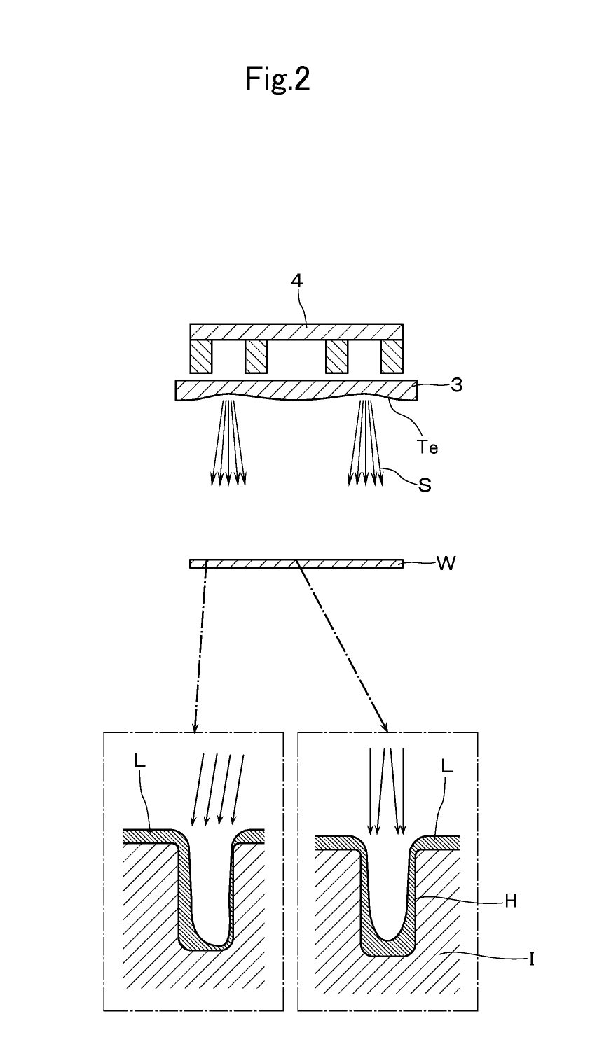

FIG. 3 is a schematic explanation of a state in which a film was formed by using the sputtering apparatus relating to an embodiment of this invention.

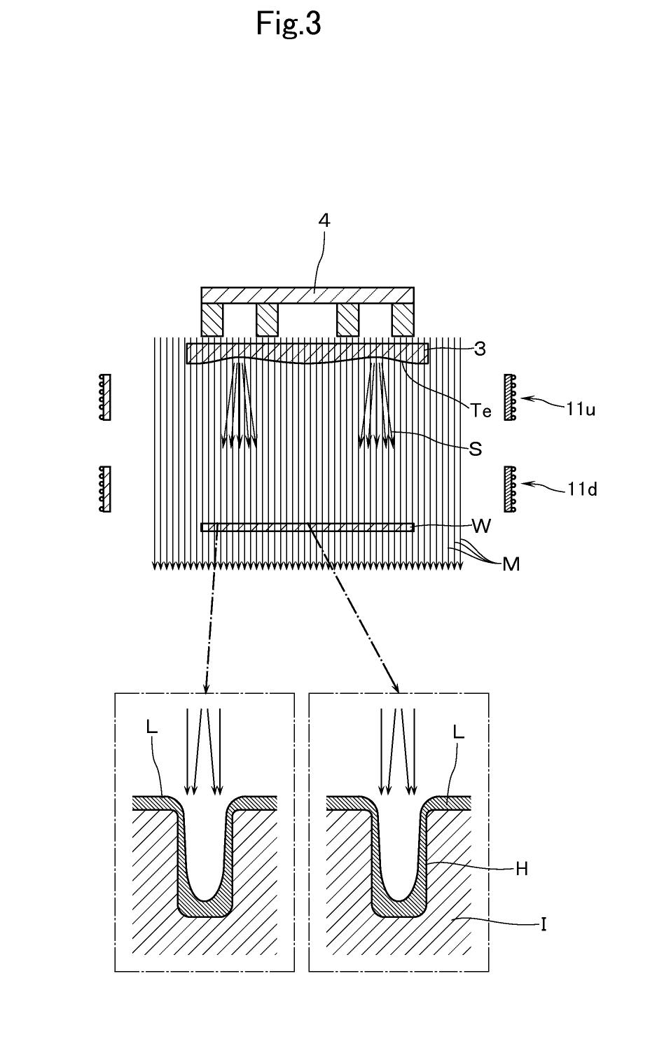

### DESCRIPTION OF REFERENCE NUMERALS AND CHARACTERS

1 DC magnetron sputtering apparatus
2 vacuum chamber
3 target
3a sputtering surface
4 magnet assembly
5 DC power supply (sputtering power supply)
7 gas pipe (gas introduction means)
11u upper coil (magnetic field generating means)
11d lower coil (magnetic field generating means)
12 power supply apparatus (magnetic field generating means)
C cathode unit
M magnetic flux
W: substrate

1. A sputtering apparatus for forming a film on a surface of a substrate disposed in a vacuum chamber, the vacuum chamber having a target disposed so as to lie opposite to the substrate, the sputtering apparatus comprising:
a magnet assembly for generating a magnetic field in front of a sputtering surface of the target;
a gas introduction means for introducing a sputtering gas into the vacuum chamber;
a sputtering power supply for charging the target with a negative potential; and
a vertical magnetic field generating means for generating a vertical magnetic field of such a nature that vertical lines of magnetic force pass through a sputtering surface of the target and through an entire surface of the substrate, the vertical lines of magnetic force being at a predetermined distance from one another.

2. The sputtering apparatus according to claim 1, wherein the magnetic field generating means comprises:
at least two coils disposed about a reference axis which connects the target and the substrate, and also at a predetermined distance from each other as seen in a longitudinal direction of the reference axis; and
a power supply apparatus which enables to supply electricity to each of the coils.

3. A sputtering method for forming a film on a surface of a substrate to be processed, the method comprising:
generating a vertical magnetic field of such a nature that vertical lines of magnetic force pass through a sputtering surface of the target and through an entire surface of the substrate, the vertical lines of magnetic force being at a predetermined distance from one another;
introducing a sputtering gas into the vacuum chamber and charging the target with a negative DC potential in a state in which the magnetic field is kept generated in front of the sputtering surface of the target, thereby forming a plasma atmosphere; and
sputtering the target to cause the sputtered particles to get adhered to, and deposited on, the surface of the substrate, thereby forming a film.

4. The sputtering method according to claim 3, wherein the vertical magnetic field is generated in a direction from the sputtered surface toward the substrate.
